(19) United States
(12) Patent Application Publication
(10) Pub. No.: US 2020/0293703 A1
(43) Pub. Date: Sep. 17, 2020

(54) MICROGRID DELAY MARGIN CALCULATION METHOD BASED ON CRITICAL CHARACTERISTIC ROOT TRACKING

(71) Applicant: SOUTHEAST UNIVERSITY, Nanjing (CN)

(72) Inventors: Wei GU, Nanjing (CN); Guannan LOU, Nanjing (CN); Ge CAO, Nanjing (CN); Wei LIU, Nanjing (CN)

(73) Assignee: SOUTHEAST UNIVERSITY, Nanjing (CN)

(21) Appl. No.: 16/618,378

(22) PCT Filed: Apr. 27, 2018
(86) PCT No.: PCT/CN2018/084937

§ 371 Date: Dec. 1, 2019

(30) Foreign Application Priority Data
Jun. 16, 2017 (CN) 201710456420.4

(51) Int. Cl. G06F 30/20; H02J 3/00

(52) U.S. Cl. CPC G06F 30/20; H02J 2203/20; H02J 3/001

(57) ABSTRACT

A microgrid delay margin calculation method based on critical characteristic root tracking includes: establishing a microgrid closed-loop small-signal model with voltage feedback control amount including communication delay based on a static output feedback, so as to obtain a characteristic equation with a transcendental term, performing critical characteristic root locus tracking for the transcendental term of the system characteristic equation, searching for a possible pure virtual characteristic root, and further calculating the maximum delay time in a stable microgrid. The method studies the relationship between the controller parameters and delay margins, thereby guiding the design of the control parameters, effectively improving the stability and dynamic performance of the microgrid.

### CROSS REFERENCE TO THE RELATED APPLICATIONS

This application is the national phase entry of International Application No. PCT/CN2018/084937, filed on Apr. 27, 2018, which is based upon and claims priority to Chinese Patent Application No. 201710456420.4, filed on Jun. 16, 2017, the entire contents of which are incorporated herein by reference.

### TECHNICAL FIELD

The present invention discloses a microgrid delay margin calculation method based on critical characteristic root tracking, and in particular to a calculation method for the delay margin of secondary voltage control in a microgrid, which belongs to the technical field of microgrid operation control.

### BACKGROUND

With the gradual depletion of earth resources and the concern of people about environmental issues, the access of renewable energy is receiving more and more attention from all the countries in the world.

As an emerging energy transmission mode that increases the penetration of renewable energies and distributed energy resources in an energy supply system, a microgrid comprises different types of distributed energy resources (DER), such as microturbines, wind-driven generators, photovoltaics, fuel cells, energy storage equipments, and the user terminals of various electrical loads and/or thermal loads and related monitoring and protection devices.

The power in the microgrid mainly depends on power electronic devices to convert energy and to provide necessary control. Relative to the main grid, the microgrid appears as a single controlled unit, which can simultaneously meet the requirements of users on the quality of electrical energy, the safety of power supply, etc. The microgrid exchanges energy with the main grid via a point of common coupling, and the two parts are standbys for each other, thus increasing the stability of power supply. As a small-scale decentralized system with a short distance from loads, the microgrid reduces power loss while increasing the reliability of local power supplies, which greatly increases the efficiency of energy utilization, so that microgrid is a novel power supply mode that meets the development requirement of intelligent power grids in the future.

Droop control has drawn attention due to the capability of realizing power sharing without communication. However, as the steady-state deviation of the output voltage of each distributed generation may occur and due to the difference of output impedances of all the distributed generations, accurate reactive power sharing can hardly be satisfactory, so that the secondary voltage control of the microgrid needs to be adopted to improve the reactive power sharing effect and voltage performance. At present, designed coordinated voltage control is of a centralized control structure in which a centralized voltage controller of the microgrid generates and sends a control signal to the local controller of each distributed generation. The centralized control structure depends on the centralized communication technology, however, the communication process is usually affected by information delay and packet loss, and the influence of information delay, packet loss and so on lead to the poor dynamic performance of the microgrid and even endanger system stability. For the aforementioned reasons, it is necessary to research a calculation method for the secondary voltage control delay margin of microgrid to analyze a maximum communication delay time in a stable microgrid, it is necessary to analyze the relationship between the centralized controller parameters of the microgrid and delay margins, consequently, the design of control parameters can be guided, and the stability and dynamic performance of the microgrid can be effectively improved.

### SUMMARY

Aimed at the phenomenon that the influence of communication delays on dynamic performance is usually neglected in the reactive power sharing and voltage recovery control of a microgrid, the present invention is directed to provide a microgrid delay margin calculation method based on critical characteristic root tracking in full consideration of the actual situation that the influence of communication delays on the system stability cannot be neglected due to the small inertia of power electronic-interfaced microgrid. By the method, all possible pure virtual characteristic roots of the microgrid characteristic equation are obtained, then the maximum delay time in a stable microgrid is calculated, and by researching the relationship between controller parameters and delay margins for stability, a guidance is provided for the design of controller parameters, solving the technical problem that the stability of existing microgrid system is affected by the communication technology.

In order to achieve the foregoing objectives, the present invention uses the following technical solutions:

Provided is a microgrid delay margin calculation method based on critical characteristic root tracking, comprising: establishing an inverter closed-loop small-signal model and a distributed generation closed-loop small-signal model with voltage feedback control amount including communication delays according to the static feedback output method, establishing a microgrid small-signal model consisting of the connection network model, the dynamic equation of load impedance and the distributed generation closed-loop small-signal model, obtaining a characteristic equation with a transcendental term from the microgrid small-signal model, performing critical characteristic root locus tracking for the transcendental term, and then determining the delay margin for the system stability.

Further, in the microgrid delay margin calculation method based on critical characteristic root tracking, the inverter closed-loop small-signal model with voltage feedback control amount including communication delay established according to the static feedback output is:

$$\{ \begin{matrix}Δ {\dot{x}}_{inv} = {A}_{inv} Δ {x}_{inv} + {B}_{inv} Δ {V}_{iDQ} + {B}_{u} Δ u \\ Δ {y}_{invQ} = {C}_{invQ} Δ {x}_{inv} , Δ {y}_{invV} = {C}_{invV} Δ {x}_{inv}\end{matrix} ,$$

Δxᵢₙᵥ and Δ\dot{x}ᵢₙᵥ respectively represent the state variables and the change rate of the closed-loop small signal model of the inverter, Δxᵢₙᵥ=[Δxᵢₙᵥ₁, Δxᵢₙᵥ₂, . . . , Δxᵢₙᵥᵢ, . . . , Δxᵢₙᵥₙ, Δφ₁, Δφ₂, . . . , Δφᵢ, . . . , Δφₙ, Δγ]^{T}, Δxᵢₙᵥ₁, Δxᵢₙᵥ₂, Δxᵢₙᵥᵢ and Δxᵢₙᵥₙ respectively represent small-signal state variables of the first, second, ith and nth distributed generations, Δφ₁, Δφ₂, Δφᵢ and Δφₙ respectively represent small-signal state variables for reactive power ancillaries of the first, second, ith and nth distributed generations, the small-signal state variable for the reactive power ancillary Δφᵢ of the ith distributed generation is determined by an expression:

$${\dot{ϕ}}_{i} = \frac{1 \text{/} {n}_{Qi}}{{\sum }_{i = 1}^{n} 1 \text{/} {n}_{Qi}} {\sum }_{i = 1}^{n} {Q}_{i} - {Q}_{i} ,$$

φᵢ represents the change rate of the small-signal state variable for the reactive power ancillary of the ith distributed generation, Qᵢ represents the actually output reactive power of the ith distributed generation, n_{Qi} represents the voltage droop characteristic coefficient of the ith distributed generation, n represents the number of the distributed generations, Δγ represents the small-signal state variable for voltage ancillary of the distributed generations, the small-signal state variable Δγ for the voltage ancillaries of the distributed generations is determined by an expression:

$$\dot{γ} = {V}_{i}^{*} - \frac{1}{n} {\sum }_{i = 1}^{n} {V}_{odi} ,$$

\dot{γ} represents the change rate of the small-signal state variable for the voltage ancillary of the distributed generations, V*ᵢ represents an expected value of the average voltage of the ith distributed generation, V_{odi} represents the d-axis component of the output voltage of the ith distributed generation under its own reference coordinate system dq, Aᵢₙᵥ represents the state matrix of the distributed generation, ΔV_{bDQ} represents the small-signal state variables of bus voltages in the common reference coordinate system DQ, ΔV_{bDQ}=[ΔV_{bDQ1}, ΔV_{bDQ2}, . . . , ΔV_{bDQ1}, . . . , ΔV_{bDQm}]^{T}, ΔV_{bDQ1}, ΔV_{bDQ2}, ΔV_{bDQ1} and ΔV_{bDQm} respectively represent the small-signal state variables of voltages of first, second, lth and mth buses in the common reference coordinate system DQ, m represents the number of the buses, Bᵢₙᵥ represents the input matrix of the distributed generations to the bus voltages, Δu represents the small-signal control amounts of the secondary voltages of the distributed generations, Δu=[Δu₁, Δu₂, . . . , Δuᵢ, . . . , Δuₙ)]^{T}, Δu₁, Δu₂, Δuᵢ and Δuₙ respectively represent the small-signal control amounts of the secondary voltages of the first, second, ith and nth distributed generations, Bᵤ represents the input matrix of the distributed generation to the small-signal control amount of the secondary voltage Δuᵢ=K_{Qi}Δy_{invQi}(t−τᵢ)+K_{Vi}Δy_{invV}(t−τᵢ), t represents the current time, τᵢ represents the communication delay between the local controller of the ith distributed generation and the centralized secondary voltage controller of microgrid, K_{Qi} and K_{Vi} respectively represent the control coefficients of the reactive power and voltage of the ith distributed generation, Δy_{invQi} represents the small-signal state variable of reactive power of the ith distributed generation, Δy_{invQ} and Δy_{invV} respectively represent the small-signal state variables of the reactive power and voltages of the distributed generations, and C_{invQ} and C_{invV} respectively represent the output matrices of reactive power and voltage of the distributed generations.

Further, in the microgrid delay margin calculation method based on critical characteristic root tracking, the distributed generation closed-loop small-signal model with voltage feedback control amount including communication delay established according to the static feedback output is:

$$\{ \begin{matrix}Δ {\dot{x}}_{inv} = {A}_{inv} Δ {x}_{inv} + {\sum }_{i - 1}^{n} {\overline{A}}_{di} Δ {x}_{inv} ( t - {τ}_{i} ) + {B}_{inv} Δ {V}_{bDQ} \\ Δ {i}_{oDQ} = {C}_{invc} Δ {x}_{inv} \end{matrix} ,$$

Ā_{di} represents the delayed state matrix of the ith distributed generation, Ā_{di}=[0 . . . BᵤᵢK_{Qi}C_{invQi}+BᵤᵢK_{Vi}C_{invV} . . . 0], Bᵤᵢ represents the input matrix of the ith distributed generation to the small-signal control amount of the secondary voltage, C_{invQi} represents the output matrix of reactive power of the ith distributed generation, Δi_{oDQ} represents the small-signal state variables of the output currents of the distributed generations in the common reference coordinate system, and C_{invc} represents the output matrix of currents of the distributed generations.

Further, in the microgrid delay margin calculation method based on critical characteristic root tracking, the microgrid small-signal model is

$$\dot{x} = Ax + {\sum }_{i - 1}^{n} {A}_{di} x ( t - {τ}_{i} ) ,$$

x and \dot{x} respectively represent the small-signal state variables and the change rate of microgrid, x=[ΔxᵢₙᵥΔi_{lineDQ}Δi_{loadDQ}]^{T}, Δi_{lineDQ} represents the small-signal state variables of the currents of connection lines between buses connected to the distributed generations in the common reference coordinate system, the small-signal state variable of the current of the connection line between the bus connected to the ith distributed generation and the bus connected to the jth distributed generation in the common reference coordinate system DQ is:

$$\{ \begin{matrix}Δ {\dot{i}}_{lineDij} = - \frac{{r}_{lineij}}{{L}_{lineij}} Δ {i}_{lineDij} + {ω}_{0} Δ {i}_{lineQij} + \frac{1}{{L}_{lineij}} ( Δ {V}_{busDi} - Δ {V}_{busDj} ) \\ Δ {\dot{i}}_{lineQij} = - \frac{{r}_{lineij}}{{L}_{lineij}} Δ {i}_{lineQij} - {ω}_{0} Δ {i}_{lineDij} + \frac{1}{{L}_{lineij}} ( Δ {V}_{busQi} - Δ {V}_{busQj} )\end{matrix} ,$$

Δi_{lineDij} and Δ\dot{i}_{lineDij} respectively represent the D-axis component of small-signal variable of the current of the connection line ij and its change rate in the common reference coordinate system, Δi_{lineQij} and Δi_{lineQij} respectively represent the Q-axis component of small-signal variable of the current of the connection line ij and its change rate in the common reference coordinate system DQ, rₗᵢₙₑᵢⱼ and Lₗᵢₙₑᵢⱼ respectively represent the line resistance and the line inductance of the connection line, ω₀ represents the rated angular frequency of the microgrid, ΔV_{busDi} and ΔV_{busQi} respectively represent the D-axis component and the Q-axis component of the voltage of the bus connected to the ith distributed generation in the common reference coordinate system DQ, ΔV_{busDj} and ΔV_{busQj} respectively represent the D-axis component and Q-axis component of the voltage of the bus connected to the jth distributed generation in the common reference coordinate system, Δi_{loadDQ} represents the small-signal state variables of the currents of loads connected to the buses in the common reference coordinate system DQ, the small-signal state variable of the current of the load connected to the lth bus in the common reference coordinate system DQ is:

$$\{ \begin{matrix}Δ {\dot{i}}_{loadDl} = - \frac{{R}_{loadl}}{{L}_{loadl}} Δ {i}_{loadDl} + {ω}_{0} Δ {i}_{loadQl} + \frac{1}{{L}_{loadl}} Δ {V}_{busDl} \\ Δ {\dot{i}}_{loadQl} = - \frac{{R}_{loadl}}{{L}_{loadl}} Δ {i}_{loadQl} - {ω}_{0} Δ {i}_{loadDl} + \frac{1}{{L}_{loadl}} Δ {V}_{busQl}\end{matrix} ,$$

Δi_{loadD1} and Δ\dot{i}_{loadD1} respectively represent the D-axis component of the current of load connected to the lth bus and the change rate of the current of the load in the common reference coordinate system DQ, Δi_{loadQl} and Δi_{loadQl} respectively represent the Q-axis component of the current of the load connected to the lth bus and its change rate in the common reference coordinate system DQ, R_{loadl} and L_{loadl} respectively represent the load resistance and the load inductance of the load connected to the lth bus, ΔV_{busDl} and ΔV_{busQl} respectively represent the D-axis component and Q-axis component of the voltage of the lth bus in the common reference coordinate system DQ, and A_{di} and τᵢ respectively represent the delayed state matrix and delay of the ith distributed generation.

As a further optimized solution of the microgrid delay margin calculation method based on critical characteristic root tracking, the method for obtaining the characteristic equation with the transcendental term from the microgrid small-signal model is as follows: when the delays of the distributed generations are consistent, the characteristic equation of the microgrid small-signal model is obtained: CE_{τ}(s,τ)=det(sI−A−A_{d}e^{-τs}), s represents the parameter of the time domain complex plane, T represents the consistent delay time of each distributed generation, CE_{τ}(⋅) represents a characteristic equation of the microgrid small-signal model obtained according to the consistent delay T of each distributed generation, det(⋅) represents the matrix determinant, I represents a unit matrix, A_{d} represents the delayed state matrix of the distributed generations,

$${A}_{d} = {\sum }_{i - 1}^{n} {A}_{di} ,$$

and e^{-τs} represents the transcendent term.

As a more further optimized solution of the microgrid delay margin calculation method based on critical characteristic root tracking, critical characteristic root locus tracking is performed for the transcendent term, then a delay margin meeting the requirement of system stability is determined, and the specific method is as follows: with a delay time ancillary variable as the variable of the characteristic equation, all pure virtual characteristic roots of the characteristic equation within the change cycle of the delay time ancillary variable are solved, a minimum value is chosen as the delay margin meeting the requirement of system stability from the critical delays corresponding to all the pure virtual characteristic roots, and the delay time ancillary variable is the product of the delay of distributed generation and the amplitude of the virtual characteristic root.

The technical solutions used in the present invention have the following beneficial effects:

(1) According to the calculation method for the secondary voltage control delay margin of the microgrid provided by the present invention, a microgrid closed-loop small-signal model with voltage feedback control amount including communication delay is established based on static output feedback, thus obtaining a characteristic equation with a transcendental term, critical characteristic root locus tracking is performed for the transcendental term of the system characteristic equation, possible pure virtual characteristic roots are searched, then a maximum delay time for a stable microgrid is calculated; the method can effectively alleviate the influence of communication delay on the dynamic performance of the microgrid, effectively improving the stability and dynamic performance of the microgrid.

(2) By solving system stability margins under different controller parameters, and researching the relationship between the controller parameters and the delay margins, the design of the controller parameters can be guided, effectively improving the stability and dynamic performance of the microgrid.

### BRIEF DESCRIPTION OF THE DRAWINGS

FIG. 1 shows the flow chart according to an embodiment of the present invention;

FIG. 2 shows the primary and secondary control block diagrams of a microgrid according to embodiment of the present invention;

FIG. 3 shows the microgrid simulation system diagram adopted in an embodiment of the present invention;

FIG. 4 shows the schematic diagram of critical characteristic root locus tracking under a certain set of controller parameters (k_{IQ}=0.02, k_{IV}=20);

FIG. 5 shows the relationship between the controller parameters and system delay margins according to an embodiment of the present invention;

FIG. 6A shows the influence of three different communication delays on the dynamic performance of average voltage under a certain set of controller parameters (k_{IQ}=0.02, k_{IV}=20) according to an embodiment of the present invention;

FIG. 6B shows the influence of three different communication delays on the dynamic performance of the reactive power of a distributed generation 1 under a certain set of controller parameters (k_{IQ}=0.02, k_{IV}=20) according to an embodiment of the present invention;

FIG. 6C shows the influence of three different communication delays on the dynamic performance of the reactive power of a distributed generation 2 under a certain set of controller parameters (k_{IQ}=0.02, k_{IV}=20) according to an embodiment of the present invention;

FIG. 7A shows the influence of three different communication delays on the dynamic performance of average voltage under a certain set of controller parameters (k_{IQ}=0.04, k_{IV}=40) according to an embodiment of the present invention;

FIG. 7B shows the influence of three different communication delays on the dynamic performance of the reactive power of the distributed generation 1 under a certain set of controller parameters (k_{IQ}=0.04, k_{IV}=40) according to an embodiment of the present invention; and

FIG. 7C shows the influence of three different communication delays on the dynamic performance of the reactive power of the distributed generation 2 under a certain set of controller parameters (k_{IQ}=0.04, k_{IV}=40) according to an embodiment of the present invention.

### DETAILED DESCRIPTION OF THE EMBODIMENTS

The following describes the technical solutions of the present invention in detail with reference to accompanying drawings.

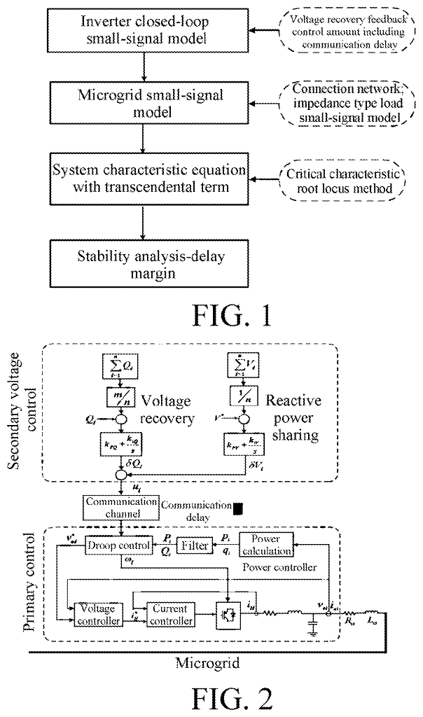

As shown in FIG. 1, the present invention discloses a microgrid delay margin calculation method based on critical characteristic root tracking, which comprises the following steps:

Step (10): Establish the inverter closed-loop small-signal model with voltage feedback control amount including communication delay based on static output feedback Each distributed generation utilizes the droop control loop in the local controller to set the references of inverter output voltage and frequency, as shown in formula (1):

$$\{ \begin{matrix}{ω}_{i} = {ω}_{n} - {m}_{Pi} {P}_{i} \\ {k}_{Vi} {\dot{V}}_{o , mogi} = {V}_{n} - {V}_{o , mogi} - {n}_{Qi} {Q}_{i}\end{matrix} . \qquad Formula ( 1 )$$

In formula (1), ωᵢ represents the local angular frequency of the ith distributed generation; ωₙ represents the reference value of the local angular frequency of the distributed generation, unit: rad/s; m_{Pi} represents the frequency droop characteristic coefficient of the ith distributed generation, unit: rad/s·W; P represents the output active power of the ith distributed generation, unit: W; k_{Vi} represents the droop control gain of the ith distributed generation; \dot{V}_{o,magi} represents the change rate of the output voltage of the ith distributed generation, unit: V/s; Vₙ represents the reference value of the output voltage of the distributed generation, unit: V; V_{o,magi} represents the output voltage of the ith distributed generation, unit: V; n_{Qi} represents the voltage droop characteristic coefficient of the ith distributed generation, unit: V/Var; and Qᵢ represents the output reactive power of the ith distributed generation, unit: Var.

The output active power Pᵢ and the output reactive power Qᵢ of the ith distributed generation are obtained by a low-pass filter, as shown in formula (2):

$$\{ \begin{matrix}{\dot{P}}_{i} = - {ω}_{ci} {P}_{i} + {ω}_{ci} ( {V}_{odi} {i}_{odi} + {V}_{oqi} {i}_{oqi} ) \\ {\dot{Q}}_{i} = - {ω}_{ci} {Q}_{i} + {ω}_{ci} ( {V}_{oqi} {i}_{odi} - {V}_{odi} {i}_{oqi} )\end{matrix} . \qquad Formula ( 2 )$$

In formula (2), \dot{P}ᵢ represents the change rate of the output active power of the ith distributed generation, unit: W/s; ω_{ci} represents the cutoff frequency of the low-pass filter of the ith distributed generation, unit: rad/s; V_{odi} represents the d-axis component of the output voltage of the ith distributed generation in the reference coordinate system dq of the ith distributed generation, unit: V; V_{oqi} represents the q-axis component of the output voltage of the ith distributed generation in the reference coordinate system dq of the ith distributed generation, unit: V; i_{odi} represents the d-axis component of the output current of the ith distributed generation in the reference coordinate system dq of the ith distributed generation, unit: A; i_{oqi} represents the q-axis component of the output voltage of the ith distributed generation in the reference coordinate system dq of the ith distributed generation, unit: A; and \dot{Q}ᵢ represents the change rate of the output reactive power of the ith distributed generation, unit: Var/s.

The primary and secondary control block diagrams of the microgrid are shown as FIG. 2, the primary control of each distributed generation makes the q-axis component of the output voltage be 0 by phase-locked loop control, and formula (3) is obtained based on the secondary voltage control of the distributed generation:

$$\{ \begin{matrix}{k}_{Vi} {\dot{V}}_{odi} = {V}_{ni} - {V}_{odi} - {n}_{Qi} {Q}_{i} + {u}_{i} \\ {V}_{oqi} = 0 \end{matrix} . \qquad Formula ( 3 )$$

In formula (3), \dot{V}_{odi} represents the change rate of the d-axis component of the output voltage of the ith distributed generation in the reference coordinate system dq of the ith distributed generation, unit: V/s; Vₙᵢ represents the reference value of the output voltage of the ith distributed generation, and uᵢ represents the secondary voltage control amount, unit: V.

A dynamic equation for the output current of the distributed generation is shown as formula (4):

$$\{ \begin{matrix}{\dot{i}}_{odi} = - \frac{{R}_{ci}}{{L}_{ci}} {i}_{odi} + {ω}_{i} {i}_{oqi} + \frac{1}{{L}_{ci}} ( {V}_{odi} - {V}_{busdi} ) \\ {\dot{i}}_{oqi} = - \frac{{R}_{ci}}{{L}_{ci}} {i}_{oqi} - {ω}_{i} {i}_{odi} + \frac{1}{{L}_{ci}} ( {V}_{oqi} - {V}_{busqi} )\end{matrix} . \qquad Formula ( 4 )$$

In formula (4), i_{odi} represents the change rate of the d-axis component of the output current of the ith distributed generation in the reference coordinate system dq of the ith distributed generation, unit: A/s; R_{ci} represents the connection resistance from the ith distributed generation to its connected bus, unit: Ω; L_{ci} represents the connection inductance from the ith distributed generation to the connected bus, unit: H; V_{busdi} represents the d-axis component of the voltage of the bus connected to the ith distributed generation in the reference coordinate system dq of the ith distributed generation; i_{oqi} represents the change rate of the q-axis component of the output current of the ith distributed generation in the reference coordinate system dq of the ith distributed generation, unit: A/s; and V_{busqi} represents the q-axis component of the voltage of the bus connected to the ith distributed generation in the reference coordinate system dq of the ith distributed generation, unit: V.

A model is established for each distributed generation on the basis of the local reference coordinate system dq. In order to establish an integrated microgrid model including a plurality of distributed generations, the reference coordinate system dq of one distributed generation is set as the common reference coordinate system DQ, the output currents of the other distributed generations in their reference coordinate systems dq need to be transformed into the common reference coordinate system, and the transformation equation is shown as formula (5):

$$[ \begin{matrix}{i}_{oDi} \\ {i}_{oQi}\end{matrix} ] = {T}_{i} [ \begin{matrix}{i}_{odi} \\ {i}_{oqi}\end{matrix} ] . \qquad Formula ( 5 )$$

In formula (5), i_{oDi} represents the D-axis component of the output current of the ith distributed generation in the common reference coordinate system DQ, and i_{oQi} represents the Q-axis component of the output current of the ith distributed generation in the common reference coordinate system, unit: A; Tᵢ represents the transformation matrix of the output current of the ith distributed generation from the reference coordinate system dq of the ith distributed generation to the common reference coordinate system DQ,

$${T}_{i} = [ \begin{matrix}cos {δ}_{i} & - sin {δ}_{i} \\ sin {δ}_{i} & cos {δ}_{i}\end{matrix} ] ,$$

δᵢ represents the difference between the rotation angle of the reference coordinate system dq of the ith distributed generation and the rotation angle of the common reference coordinate system DQ, unit: degree, and δᵢ can be obtained by formula (6):

\dot{δ}ᵢ=ωᵢ−ω_{com} Formula (6).

In formula (6), ω_{com} represents the angular frequency of the common reference coordinate system DQ; and \dot{δ}ᵢ represents the change rate of δᵢ.

Formulas (1)-(6) are linearized to obtain an open-loop small-signal model of the ith distributed generation shown as formula (7):

$$\{ \begin{matrix}Δ {\dot{x}}_{invi} = {A}_{invi} Δ {x}_{invi} + {B}_{invi} Δ {V}_{bDQi} + {B}_{iwcom} {Δω}_{com} + {B}_{ui} Δ {u}_{i} \\ Δ {i}_{oDQi} = {C}_{invci} Δ {x}_{invi} \end{matrix} . \qquad Formula ( 7 )$$

In formula (7), Δ\dot{x}ᵢₙᵥᵢ represents the change rate of the small-signal state variables of the ith distributed generation, Δ\dot{x}ᵢₙᵥᵢ=[Δ\dot{δ}ᵢ, Δ\dot{P}ᵢ, Δ\dot{Q}ᵢ, Δ\dot{V}_{odi}, Δ\dot{i}_{odi}, Δ\dot{i}_{oqi}]^{T}; Δxᵢₙᵥᵢ represents the small-signal state variables of the ith distributed generation, Δxᵢₙᵥᵢ=[Δδᵢ, ΔPᵢ, ΔQᵢ, ΔV_{odi}, Δi_{odi}, Δi_{oqi}]^{T}; ΔV_{bDQi} represents the small-signal state variables of the voltage of the bus connected to the ith distributed generation in the common reference coordinate system DQ; ΔV_{bDQi}=[ΔV_{bDi}, ΔV_{bQi}]^{T}, ΔV_{bDi} represents the D-axis small-signal component of the voltage of the bus connected to the ith distributed generation in the common reference coordinate system DQ, and ΔV_{bQi} represents the Q-axis small-signal component of the voltage of the bus connected to the ith distributed generation in the common reference coordinate system DQ, unit: V; Δω_{com} represents the small-signal state variable of the angular frequency of the common reference coordinate system DQ, unit: rad/s; Δuᵢ represents the small-signal control amount of the secondary voltage of the ith distributed generation, unit: V; Aᵢₙᵥᵢ represents the state matrix of the ith distributed generation; Bᵢₙᵥᵢ represents the input matrix of the ith distributed generation to the voltage of the connected bus; B_{iwcom} represents the input matrix of the ith distributed generation to the angular frequency of the common reference coordinate system; Bᵤᵢ represents the input matrix of the ith distributed generation to the small-signal control amount of the secondary voltage; Δi_{oDQi} represents the small-signal state variables of the output current of the ith distributed generation in the common reference coordinate system DQ, ΔΔi_{oDQi}=[Δi_{oDi}, Δi_{oQi}]^{T}, unit: A; and C_{invci} represents the output current matrix of the ith distributed generation.

According to formula (7), ΔV_{busDQi} and Δω_{com} serve as disturbance variables of the ith distributed generation, where the reference coordinate system of the first distributed generation is generally selected as the common reference coordinate system DQ, then

Δω_{com}=[0−m_{P1} 0 0 0 0]Δxᵢₙᵥ₁ Formula (8).

In formula (8), m_{P1} represents the frequency droop characteristic coefficient of the first distributed generation, unit: rad/s·W; Δxᵢₙᵥ₁ represents the small-signal state variables of the first distributed generation, Δxᵢₙᵥ₁=[Δδ₁, ΔPᵢ, Δ_{Q1}, ΔV_{od1}, Δi_{od1}, Δi_{oq1}]^{T}.

According to formula (7) and formula (8), the small-signal model of the system consisting of n distributed generations can be obtained:

$$\{ \begin{matrix}Δ {\dot{\overline{x}}}_{inv} = {\overline{A}}_{inv} Δ {\overline{x}}_{inv} + {\overline{B}}_{inv} Δ {V}_{bDQ} + {\overline{B}}_{u} Δ u \\ Δ {i}_{oDQ} = {\overline{C}}_{invc} Δ {\overline{x}}_{inv} \end{matrix} . \qquad Formula ( 9 )$$

In formula (9), Δx̅ᵢₙᵥ=[Δxᵢₙᵥ₁Δxᵢₙᵥ₂ . . . Δᵢₙᵥₙ], Δxᵢₙᵥ₁ represents the small-signal state variables of the first distributed generation, Δxᵢₙᵥ₂ represents the small-signal state variables of the second distributed generation, and Δxᵢₙᵥₙ represents the small-signal state variables of the nth distributed generation; ΔV_{bDQ}=[ΔV_{bDQ1} ΔV_{bDQ2} . . . ΔV_{busDQm}]^{T}, ΔV_{bDQ1}=[ΔV_{bD1}ΔV_{bQ1}]^{T}, ΔV_{BD1} represents the D-axis component of small-signal variable of the voltage of bus 1 in the common reference coordinate system DQ, ΔV_{bQ1} represents the Q-axis component of small-signal variable of the voltage of bus 1 in the common reference coordinate system DQ, ΔV_{bDQ2}=[ΔV_{bD2} ΔV_{bQ2}]^{T}, ΔV_{bD2} represents the D-axis component of small-signal variable of the voltage of bus 2 in the common reference coordinate system DQ, ΔV_{bQ2} represents the Q-axis component of small-signal variable of the voltage of bus 2 in the common reference coordinate system DQ, ΔV_{bDQm}=[ΔV_{bDm} ΔV_{bQm}]^{T}, ΔV_{bDm} represents the D-axis component of small-signal variable of the voltage of bus m in the common reference coordinate system DQ, and ΔV_{bQm} represents the Q-axis component of small-signal variable of the voltage of bus m in the common reference coordinate system DQ; Δu=[Δu₁Δu₂ . . . Δuₙ]^{T}, Δi_{oD1} represents the small-signal control amount of the secondary voltage of the distributed generation 1, Δu₂ represents the small-signal control amount of the secondary voltage of the distributed generation 2, and Δuₙ represents the small-signal control amount of the secondary voltage of the distributed generation n; Δi_{oDQ}=[Δi_{oDQl}Δi_{oDQ2} . . . Δi_{oDQn}]^{T}, Δi_{oDQ1}=[Δi_{oD1}, Δi_{oQ1}]^{T}, Δi_{oD1} represents the D-axis component of small-signal variable of the output current of the first distributed generation in the common reference coordinate system DQ, Δi_{oQ1} represents the Q-axis component of small-signal variable of the output current of the ith distributed generation in the common reference coordinate system DQ, Δi_{oDQ2}=[Δi_{oD2}, Δi_{oQ2}]^{T}, Δi_{oD2} represents the D-axis component of small-signal variable of the output current of the second distributed generation in the common reference coordinate system DQ, and Δi_{oQ2} represents the Q-axis component of small-signal variable of the output current of the second distributed generation in the common reference coordinate system DQ; Δi_{oDQn}=[Δi_{oDn}, Δi_{oQn}]^{T}, Δi_{oDn} represents the D-axis component of small-signal variable of the output current of the nth distributed generation in the common reference coordinate system DQ, Δi_{oQn} represents the Q-axis component of small-signal variable of the output current of the nth distributed generation in the common reference coordinate system DQ, and Āᵢₙᵥ represents the state matrix of n distributed generations; B̅ᵢₙᵥ represents the input matrix of n distributed generations to bus voltages; \hat{B}ₙ represents the input matrix of the n distributed generations to the small-signal control amount of the secondary voltage; and C̅_{invc} represents the current output matrix of the n distributed generations.

Based on the control requirements of reactive power sharing and voltage recovery, the present invention realizes microgrid voltage control. Reactive power sharing refers to that the output reactive power of each distributed generation is allocated according to the power capacity, voltage recovery refers to that the average output voltage of all the distributed generations is recovered to a rated value, and the following dynamic equation is first defined:

$$\{ \begin{matrix}{\dot{ϕ}}_{i} = {Q}_{i}^{*} - {Q}_{i} = \frac{1 \text{/} {n}_{Qi}}{{\sum }_{i = 1}^{n} 1 \text{/} {n}_{Qi}} {\sum }_{i = 1}^{n} {Q}_{i} - {Q}_{i} \\ \dot{γ} = {V}_{i}^{*} - {\overline{V}}_{od} = {V}_{i}^{*} - \frac{1}{n} {\sum }_{i = 1}^{n} {V}_{odi}\end{matrix} . \qquad Formula ( 10 )$$

In formula (10), \dot{φ}ᵢ represents the change rate of the small-signal state variable of reactive power ancillary of the ith distributed generation, unit: Var; Qᵢ: represents the expected output reactive power of the ith distributed generation, unit: Var; n_{Qi} represents the voltage droop characteristic coefficient of the ith distributed generation, unit: V/Var; γ̅ represents the change rate of the small-signal state variable for the voltage ancillary of the distributed generation, unit: V; V̅_{od} represents the average output voltage of all distributed generations, and V*ᵢ represents the expected average voltage of the ith distributed generation, unit: V.

Therefore, an inverter closed-loop small-signal model based on output feedback is:

$$\{ \begin{matrix}Δ {\dot{x}}_{inv} = {A}_{inv} Δ {x}_{inv} + {B}_{inv} Δ {V}_{bDQ} + {B}_{u} Δ u \\ Δ {y}_{invQ} = {C}_{invQ} Δ {x}_{inv} , Δ {y}_{invV} = {C}_{invV} Δ {x}_{inv}\end{matrix} . \qquad Formula ( 11 )$$

In formula (11), Δxᵢₙᵥ represents the closed-loop small-signal state variables of n inverters, Δxᵢₙᵥ=[Δxᵢₙᵥᵢ, Δxᵢₙᵥ₂, . . . , Δxᵢₙᵥᵢ, . . . , Δxᵢₙᵥₙ, Δφ₁, Δφ₂, . . . , Δφᵢ, . . . , Δφₙ, Δγ]^{T}, Δφ₁ small-signal state variable of a reactive power ancillary of the first distributed generation, Δφ₂ represents the small-signal state variable of a reactive power ancillary of the second distributed Δφ₂ generation, Δφᵢ represents the small-signal state variable of the reactive power ancillary of the ith distributed generation, Δφₙ represents the small-signal state variable of the reactive power ancillary of the nth distributed generation, and Δγ represents the small-signal state variable for voltage ancillary of distributed generations; Δy_{invQ} represents small-signal state variables of output reactive powers Δy_{invQ}=[Δ\dot{φ}₁ Δφ₁ Δ\dot{φ}₂ Δφ₂ . . . Δφₙ Δφₙ], Δ\dot{φ}₁ represents the change rate of the small-signal state variable of the reactive power ancillary of the first distributed generation, Δ\dot{φ}₂ represents the change rate of small-signal state variable of the reactive power ancillary of the second distributed generation, and Δ\dot{φ}ₙ represents the change rate of small-signal state variable of the reactive power ancillary of the nth distributed generation; Δy_{invV} represents the small-signal state variables of the output voltage of the distributed generations, Δy_{invV}=[Δ\dot{γ}, Δγ]^{T}, and Δ\dot{γ} represents the change rate of small-signal state variable for the voltage ancillary of each distributed generation; C_{invQ} represents the output matrix of reactive power of distributed generations; and C_{invV} represents the output matrix of the voltages of distributed generations.

The control amount of the distributed generation is defined as:

$$\{ \begin{matrix}δ {Q}_{i} = {k}_{PQ} ( {Q}_{i}^{*} - {Q}_{i} ) + {k}_{IQ} ϕ \\ δ {V}_{i} = {k}_{PV} ( {V}^{*} - {\overline{V}}_{od} ) + {k}_{IV} γ\end{matrix} . \qquad Formula ( 12 )$$

In formula (12), δQᵢ represents the reactive power control signal of the ith distributed generation; k_{PQ} represents the proportional term coefficient in a reactive power proportional-integral controller; k_{IQ} represents the integral term coefficient in the reactive power proportional-integral controller; δVᵢ represents the average voltage recovery control signal of the ith distributed generation; k_{PV} represents the proportional term coefficient in the average voltage proportional-integral controller; and k_{IV} represents the integral term coefficient in the average voltage proportional-integral controller.

When a communication delay exists between a centralized voltage controller of the microgrid and each distributed generation, a voltage control amount is:

Δᵤᵢ=Δδ_{Qi}(t−τᵢ)+Δδ_{Vi}(t−τᵢ)=K_{Qi}Δy_{invQi}(t−τᵢ)+K_{Vi}Δy_{invV}(t−τᵢ) Formula (13).

In formula (13), τᵢ represents the communication delay between the local controller of the ith distributed generation and the centralized secondary voltage controller of the microgrid, unit: s; K_{Qi} represents the reactive power controller of the ith distributed generation, K_{Qi}=[k_{PQi} k_{IQi}]; and K_{Vi} represents the voltage controller of the ith distributed generation, K_{Vi}=[k_{PVi} k_{IVi}].

By reference to formulas (11)-(13), the close-loop small-signal model of n distributed generations are obtained:

$$\{ \begin{matrix}Δ {\dot{x}}_{inv} = {A}_{inv} Δ {x}_{inv} + {\sum }_{i = 1}^{n} {\overline{A}}_{di} Δ {x}_{inv} ( t - {τ}_{i} ) + {B}_{inv} Δ {V}_{bDQ} \\ Δ {i}_{oDQ} = {C}_{invc} Δ {x}_{inv} \end{matrix} . \qquad Formula ( 14 )$$

In formula (14), Ā_{dx} represents the delayed state matrix of the ith distributed generation,

Ā_{di}=[0 . . . BᵤᵢK_{Qi}C_{invQi}+BᵤᵢK_{Vi}C_{invV} . . . 0], Bᵤᵢ represents the input matrix of the ith distributed generation to the small-signal control amount of the secondary voltage, C_{invQi} represents the output matrix of reactive power of the ith distributed generation, and C_{invc} represents the output matrix of the current of the distributed generation.

Step (20) Establish a microgrid small-signal model according to a connection network and a dynamic equation of load impedance

A current small-signal dynamic equation of a connection line ij between the bus connected to the ith distributed generation and the bus connected to the jth distributed generation in the common reference coordinate system DQ is shown as formula (15):

$$Formula ( 15 )$$

$$\{ \begin{matrix}Δ {\dot{i}}_{lineDij} = - \frac{{r}_{lineij}}{{L}_{lineij}} Δ {i}_{lineDij} + {ω}_{0} Δ {i}_{lineQij} + \frac{1}{{L}_{lineij}} ( Δ {V}_{busDi} - Δ {V}_{busDj} ) \\ Δ {\dot{i}}_{lineQij} = - \frac{{r}_{lineij}}{{L}_{lineij}} Δ {i}_{lineQij} - {ω}_{0} Δ {i}_{lineDij} + \frac{1}{{L}_{lineij}} ( Δ {V}_{busQi} - Δ {V}_{busQj} )\end{matrix} .$$

In formula (15), Δi_{lineDij} represents the change rate of a D-axis component of small-signal variable of the current of the ijth connection line in the common reference coordinate system DQ, unit: A/s; rₗᵢₙₑᵢⱼ represents the line resistance of the ijth connection line, unit: Ω; Lₗᵢₙₑᵢⱼ represents the line inductance of the ijth connection line, unit: H; Δi_{lineDij} represents the D-axis component of small-signal variable of the current of the ijth connection line in the common reference coordinate system DQ, and Δi_{lineQij} represents the Q-axis component of small-signal variable of the current of the ijth connection line in the common reference coordinate system DQ, unit: A; ω₀ represents the rated angular frequency of the microgrid, unit: rad/s; ΔV_{busDi} represents the D-axis component of small-signal variable of the voltage of the bus connected to the ith distributed generation in the common reference coordinate system DQ; ΔV_{busDj} represents the D-axis component of small-signal variable of the voltage of the bus connected to the jth distributed generation in the common reference coordinate system DQ; Δi_{lineQij} represents the change rate of the Q-axis component of small-signal variable of the current of the ijth connection line in the common reference coordinate system DQ, unit: A/s; ΔV_{busQi} represents the Q-axis component of small-signal variable of the voltage of the bus connected to the ith distributed generation in the common reference coordinate system DQ, and ΔV_{busQj} represents the Q-axis component of small-signal variable of the voltage of the bus connected to the jth distributed generation in the common reference coordinate system DQ, unit: V.

A current dynamic equation of a load connected to the lth bus in the common reference coordinate system DQ is shown as formula (16):

$$\{ \begin{matrix}Δ {\dot{i}}_{loadDt} = - \frac{{R}_{loadl}}{{L}_{loadl}} Δ {i}_{loadDl} + {ω}_{0} Δ {i}_{loadQl} + \frac{1}{{L}_{loadl}} Δ {V}_{busDl} \\ Δ {\dot{i}}_{loadQt} = - \frac{{R}_{loadl}}{{L}_{loadl}} Δ {i}_{loadQl} - {ω}_{0} Δ {i}_{loadDl} + \frac{1}{{L}_{loadl}} Δ {V}_{busQl}\end{matrix} . \qquad Formula ( 16 )$$

In formula (16), Δi_{loadD1} represents the change rate of D-axis component of small-signal variable of the current of the load connected to the lth bus in the common reference coordinate system DQ, unit: A/s; R_{load1} represents the load resistance of the load connected to the lth bus, unit: Ω; L_{load1} represents the load inductance of the load connected to the lth bus, unit: H; Δi_{loadDl} represents the D-axis component of small-signal variable of the current of the load connected to the lth bus in the common reference coordinate system DQ, and Δi_{loadQl} represents the Q-axis component of small-signal variable of the current of the load connected to the lth bus in the common reference coordinate system DQ, unit: A; and Δi_{loadQl} represents the change rate of Q-axis component of small-signal variable of the current of the load connected to the lth bus in the common reference coordinate system DQ, unit: A/s.

A small-signal equation of the connection line between the bus connected to the ith distributed generation and the bus connected to the jth distributed generation is set as formula (17):

$$\{ \begin{matrix}Δ {V}_{busDj} = {R}_{loadj} ( Δ {i}_{oDj} + Δ {i}_{lineDij} - Δ {i}_{lineDij} ) + {L}_{loadj} [ ( Δ {i}_{oDj} + Δ {i}_{lineDij} - Δ {i}_{lineDij} ) - {ω}_{0} ( Δ {i}_{oQj} + Δ {i}_{lineQij} - Δ {i}_{lineQij} ) ] \\ Δ {V}_{busQj} = {R}_{loadj} ( Δ {i}_{oQj} + Δ {i}_{lineQij} - Δ {i}_{lineQij} ) + {L}_{loadj} [ ( Δ {i}_{oQj} + Δ {i}_{lineQij} - Δ {i}_{lineQij} ) + {ω}_{0} ( Δ {i}_{oDj} + Δ {i}_{lineDij} - Δ {i}_{lineDij} ) ]\end{matrix} . \qquad Formula ( 17 )$$

In formula (17), R_{loadj} and L_{loadj} respectively represent the resistance value and the inductance value of a load on the bus connected the jth distributed generation; and Δi_{oDj} and Δi_{oQj} respectively represent the D-axis component small-signal variable and Q-axis component of small-signal variable of the output current of the jth distributed generation in the common reference coordinate system DQ.

Formula (17) is substituted into formulas (14)-(16) to obtain the microgrid small-signal model comprising n distributed generations, s branches and p loads:

$$\dot{x} = Ax + {\sum }_{i = 1}^{n} {A}_{di} x ( t - {τ}_{i} ) . \qquad Formula ( 18 )$$

In formula (18), x represents the microgrid small-signal state variables, x=[Δxᵢₙᵥ Δi_{lineDQ} Δi_{loadDQ}]^{T}, Δi_{lineDQ} represent the small-signal state variables of the current of the connection lines between the buses connected to the distributed generations in the common reference coordinate system DQ, and Δi_{loadDQ} represent the small-signal state variables of the current of the loads connected to the buses in the common reference coordinate system DQ; \dot{x} represents the change rate of the microgrid small-signal state variables; A represents the microgrid state matrix; A_{di} represents the delayed state matrix of the ith distributed generation; and τᵢ represents the delay of the ith distributed generation.

Step (30) Obtain a characteristic equation with a transcendental term of a microgrid closed-loop small-signal model

When the delays of all the distributed generations are consistent, a characteristic equation of formula (18) is formula (19):

CE_{τ}(s,τ)=det(sI−A−A_{d}e^{-τs}) Formula (19).

In formula (19), s represents the parameter of the time domain complex plane; r represents the consistent delay time of each distributed generation, τ₁=τ₂= . . . =τₙ, unit: s; det(⋅) represents the matrix determinant; I represents the unit matrix; A_{d} represents the delayed state matrix of the distributed generation, A_{d}=Σᵢ₌₁ⁿA_{di}; and e^{-τs} represents the transcendental term.

Step (40) Carry out critical characteristic root locus tracking for the transcendental term of the system characteristic equation to calculate the system stability margin For formula (19), if all system characteristic roots are on the left half of a complex plane, the system is stable; if there are characteristic roots on the right half of the complex plane, the system is unstable; and if there are characteristic roots on the left half of the complex plane or the imaginary axis, the system is critically stable. Because the system characteristic roots continuously change along with the delay time τ, in order to determine the system stability margin Td, that is, the system is stable if r is less than Td, and is unstable if r is greater than Td, the possible pure virtual characteristic roots and the corresponding delay margin need to be determined.

ξ=τω is defined and substituted into formula (19), and then,

CE_{ξ}(s,ξ)=det(sI−A−A_{d}e^{-iξ}) Formula (20).

Where, ξ represents the delay time ancillary variable, and ω represents the virtual characteristic root amplitude; here, i represents the imaginary unit, and i²=−1. ξ changes within the cycle of [0, 2π], so that corresponding characteristic roots of formula (20) are obtained. If there are pure virtual characteristic roots corresponding to certain ξ then a critical delay time is:

τ_{c}=ξ_{c}/abs(ω_{C}) Formula (21).

In the formula, ξ_{c} represents the delay time ancillary variable for the existence of pure virtual characteristic roots in the system, abs(ωc) represents the amplitude of the corresponding pure virtual characteristic root, and τ_{c} represents the critical delay time.

When ξ changes within the cycle of [0, 2π], there may be a plurality of critical delay times in the system, i.e. τ_{c1}, τ_{c2} . . . τ_{cL}, and the minimum value τ_{d} is selected as the delay margin:

τ_{d}=min(τ_{c1} τ_{c2} . . . τ_{cL}) Formula (22).

In the aforementioned embodiment, the common reference coordinate system DQ refers to the reference coordinate system dq of the first distributed generation, and the state variables of the other distributed generations, branch currents and load currents are transformed into the common reference coordinate system DQ by the transformation of coordinates. In step (10), because the proportional term coefficients in the proportional-integral controller of reactive power and the proportional-integral controller of the voltage are small, in practice, the proportional-integral controller of reactive power and the proportional-integral controller of the voltage can be respectively simplified into an integral controller of reactive power and an integral controller of voltage. In step (20), the loads are impedance type loads.

In the present embodiment, by introducing the microgrid closed-loop small-signal model of signal communication delay time, a system characteristic equation with a transcendental term is established, and thereby the microgrid delay margin calculation method based on critical characteristic root tracking is implemented. Aimed at the conventional microgrid secondary control method which neglects the influence of the communication delay on the dynamic performance of the system, the present embodiment works out a maximum delay time for maintaining the system stable in full consideration of the actual situation that the influence of the communication delay on system stability cannot be neglected due to the low inertia of power electronic interfaced microgrid. By analyzing the relationship between different controller parameters and delay margins, the delay margin calculation method of the present embodiment guides the design of the controllers, thus improving the stability and dynamic performance of the system.

The block diagram of the microgrid control system in the embodiment of the present invention is shown as FIG. 2. The control block diagram mainly comprises two layers: the first layer is the local controller of each distributed generation, which consists of power calculation, droop control, and a voltage and current double loop; and the second layer is the secondary voltage control layer, which realizes reactive power sharing and average voltage recovery. The centralized secondary voltage controller acquires the output voltage and output reactive power of each distributed generation, works out the secondary voltage control amount of each distributed generation, then sends a control instruction into each local controller. In the process of sending the control instruction, a communication delay exists between the centralized secondary voltage controller and the local controller of each distributed generation, and this delay affects the dynamic performance of the system.

The following exemplifies an embodiment.

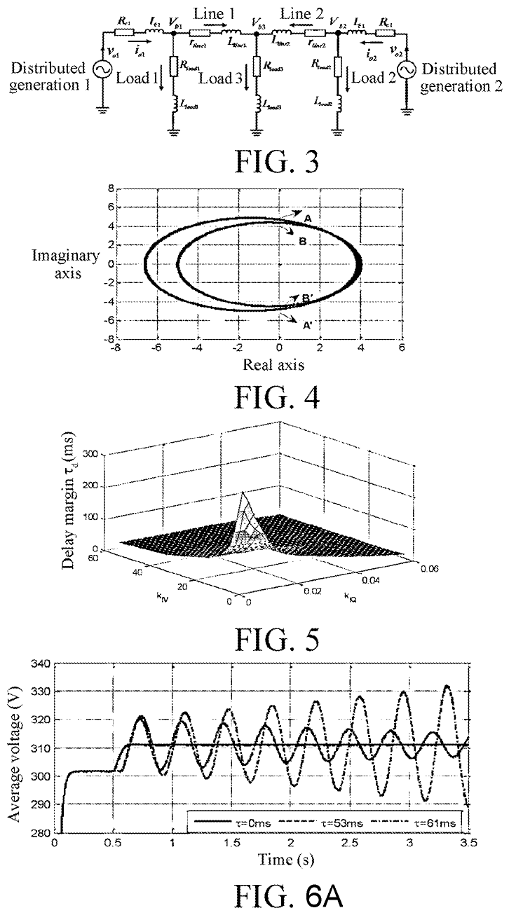

A simulation system is shown as FIG. 3, a microgrid consists of two distributed generations, two connection lines, and three loads, the load 1 is connected to bus 1, the load 2 is connected to bus 2, and the load 3 is connected to bus 3. In the system, impedance type loads are adopted as the loads. If the capacity ratio of the distributed generation 1 and the distributed generation 2 is 1:1, then corresponding frequency droop coefficient and voltage droop coefficient are designed to make the ratio of the expected output active power and reactive power of two distributed generations be equal to 1:1. Theoretical delay margins of the microgrid under different controller parameters are studied, and a microgrid simulation model is established based on an MATLAB/Simulink platform to simulate and verify the theoretical delay margins.

FIG. 4 is the schematic diagram of critical characteristic root locus tracking associated with system stability under controller parameters (k_{IQ}=0.02, k_{IV}=20). A communication delay ancillary variable ξ change within [0, 2π], two pairs of conjugate characteristic roots are closely related to system stability, four critical characteristic roots A(jω_{c1}), A′(−jω_{c1}), B(jω_{c2}) and B′(jω_{c2}) passing through the imaginary axis of a complex plane and corresponding ξ are recorded, and a delay margin τd=0.05888 s is worked out according to formula (21) and formula (22).

FIG. 5 is the relationship between the microgrid delay margin calculated based on critical characteristic root tracking and the controller parameters under the controller parameters (0.005≤k_{IQ}≤0.06, 5≤k_{IV}≤60) in the embodiment of the present invention. It can be known from the drawing that with an increase in the integral coefficient k_{IQ} of the reactive power controller and the integral coefficient k_{IV} of the voltage controller, the delay margin of the system decreases. That is, the robust stability of the system reduced. Therefore, when different combinations of controller parameters achieve similar dynamic performance, the delay margin will serve as an additional robust stability index to guide the design of the controller parameters, providing the system with stability and dynamic performance.

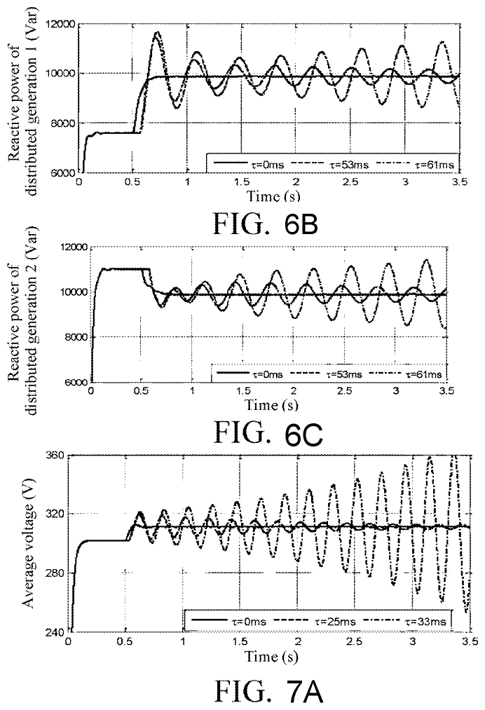

FIG. 6 is the simulation result of a decentralized control method for the influence of three different communication delays on the dynamic performance of the system under a certain set of controller parameters (k_{IQ}=0.02, k_{IV}=20) of the microgrid according to the embodiment of the present invention. When the system is started, each distributed generation operates under a droop control mode, and at 0.5 s, secondary voltage control is put into operation. A simulation result is shown as FIG. 6, FIG. 6A is an average voltage curve graph of the distributed generation in the microgrid, the X axis represents time, unit: s, and the Y axis represents average voltage, unit: V. W. As shown in FIG. 6A, at the beginning, under the effect of droop control, a steady-state deviation exists in the average voltage of the distributed generations, and after 0.5 s, under the effect of secondary control, the voltage amplitude increases. It can be known from FIG. 6A that when no communication delay exists in the system, the average voltage is so smooth as to reach a rated value; when the delay time is 53 ms, the voltage curve experiences decreased oscillation and restores; when the delay time is 61 ms, the curve experiences increasing oscillation, and the system is unstable. FIG. 6B is a reactive power output curve graph of the distributed generation 1, unit: s, and the Y axis represents reactive power, unit: Var. It can be known from FIG. 6B that at the beginning, under the effect of droop control, the reactive power sharing effect is not satisfactory (less than the expected output reactive power value of the distributed generation 1), and after 0.5 s, under the effect of secondary control, reactive power output is increased. It can be known from FIG. 6B that when no communication delay exists in the system, the reactive power is so smooth as to reach an expected value; when the delay time is 53 ms, the power curve experiences decreased oscillation and reaches the control target; when the delay time is 61 ms, the curve experiences increasing oscillation, and the system is unstable. Under the effect of secondary control, the reactive power sharing effect of the microgrid is significantly improved. FIG. 6C is a reactive power output curve graph of the distributed generation 2, unit: s, and the Y axis represents reactive power, unit: Var. It can be known from FIG. 6C that at the beginning, under the effect of droop control, the reactive power sharing effect is not satisfactory (higher than an expected output reactive power value of the distributed generation 2), and after 0.5 s, under the effect of secondary control, reactive power output is decreased. It can be known from FIG. 6C that when no communication delay exists in the system, reactive power is so smooth as to reach an expected value; when the delay time is 53 ms, the power curve experiences decreased oscillation and reaches a control target; when the delay time is 61 ms, the curve experiences increasing oscillation, and the system is unstable. It can be known from FIG. 6 that the delay margin of the system under the controller parameters is between 53 ms and 61 ms, and is consistent with a theoretical calculated value.

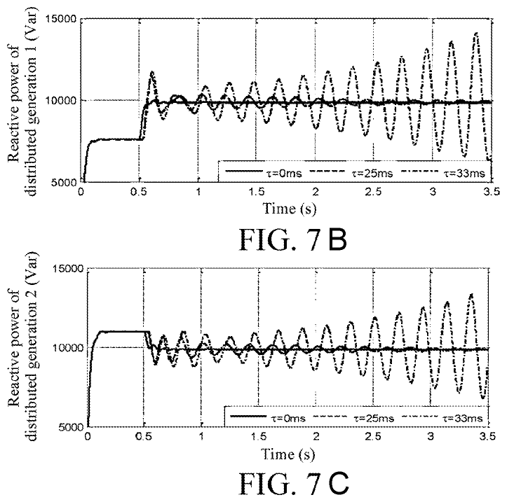

FIG. 7 is the simulation result of a decentralized control method for the influence of three communication delays on the dynamic performance of the system under a certain set of controller parameters (k_{IQ}=0.04, k_{IV}=40) of the microgrid according to the embodiment of the present invention. When operation is started, each distributed generation operates under a droop control mode, and at 0.5 s, secondary voltage control is put into operation. A simulation result is shown as FIG. 7, FIG. 7A is the average voltage curve graph of the distributed generations in the microgrid, the X axis represents time, unit: s, and the Y axis represents average voltage, unit: V. W. As shown in FIG. 7A, at the beginning, under the effect of droop control, a steady-state deviation exists in the average voltage of the distributed generations, and after 0.5 s, under the effect of secondary control, the voltage amplitude increases. It can be known from FIG. 7A that when no communication delay exists in the system, the average voltage is so smooth as to reach a rated value; when the delay time is 25 ms, the voltage curve experiences decreased oscillation and restores; when the delay time is 33 ms, the oscillation of the curve experiences increasing oscillation, and the system is unstable. FIG. 7B is the reactive power output curve graph of the distributed generation 1, unit: s, and the Y axis represents reactive power, unit: Var. It can be known from FIG. 7B that at the beginning, under the effect of droop control, the reactive power sharing effect is not satisfactory (less than an expected output reactive power value of the distributed generation 1), and after 0.5 s, under the effect of secondary control, reactive power output is increased. It can be known from FIG. 6B that when no communication delay exists in the system, reactive power is so smooth as to reach an expected value; when the delay time is 25 ms, the power curve reaches a control objective due to decreased oscillation; when the delay time is 33 ms, the oscillation of the curve is increased, and the system is unstable. Under the effect of secondary control, the reactive power sharing effect of the microgrid is significantly improved. FIG. 7C is the reactive power output curve graph of the distributed generation 2, unit: s, and the Y axis represents reactive power, unit: Var. It can be known from FIG. 7C that at the beginning, under the effect of droop control, the reactive power sharing effect is not satisfactory (higher than an expected reactive power output value of the distributed generation 2), and after 0.5 s, under the effect of secondary control, reactive power output is decreased. It can be known from FIG. 7C that when no communication delay exists in the system, reactive power is so smooth as to reach an expected value; when the delay time is 25 ms, the power curve experiences decreased oscillation and reaches the control target; when the delay time is 33 ms, the curve experiences increasing oscillation, and the system is unstable. It can be known from FIG. 6 that the delay margin of the system under the controller parameters is between 25 ms and 33 ms, and is consistent with a theoretical calculated value.

The method of the embodiment of the present invention is a microgrid delay margin calculation method based on critical characteristic root tracking, by which the microgrid closed-loop small-signal model including communication delay is established based on the output feedback method, and the maximum delay time for a stable system, i.e. the delay margin is analyzed. Aimed at the conventional microgrid secondary control method which neglects the influence of communication delay on the dynamic performance of the system, the present embodiment takes the influence of communication delay on system stability into full consideration, and in addition, by studying the relationship between different controller parameters and delay margins, the design of the controllers is guided, thus improving the robust stability and dynamic performance of the microgrid.

What is claimed is:

1. A microgrid delay margin calculation method based on a critical characteristic root tracking, comprising: establishing an inverter closed-loop small-signal model and a distributed generation closed-loop small-signal model of a voltage feedback control amount comprising a communication delay according to a static feedback output, establishing a microgrid small-signal model consisting of a connection network, a dynamic equation of a load impedance and the distributed generation closed-loop small-signal model, obtaining a characteristic equation with a transcendental term from the microgrid small-signal model, performing the critical characteristic root tracking on the transcendental term, and then determining a delay margin meeting a requirement of a system stability.

2. The microgrid delay margin calculation method based on the critical characteristic root tracking according to claim 1, wherein, the inverter closed-loop small-signal model of the voltage feedback control amount comprising the communication delay established according to the static feedback output is:
$$\{ \begin{matrix}Δ {\dot{x}}_{inv} = {A}_{inv} Δ {x}_{inv} + {B}_{inv} Δ {V}_{bDQ} + {B}_{u} Δ u \\ Δ {y}_{invQ} = {C}_{invQ} Δ {x}_{inv} , Δ {y}_{invV} = {C}_{invV} Δ {x}_{inv}\end{matrix} ,$$
Δxᵢₙᵥ and Δ\dot{x}ᵢₙᵥ respectively represent a closed-loop small-signal state variable and a change rate of an inverter, Δxᵢₙᵥ=[Δxᵢₙᵥ₁, Δxᵢₙᵥ₂, . . . , Δxᵢₙᵥᵢ, . . . , Δxᵢₙᵥₙ, Δφ₁, Δφ₂, . . . , Δφᵢ, . . . , Δφₙ, Δγ]^{T}, Δxᵢₙᵥ₁, Δxᵢₙᵥ₂, Δxᵢₙᵥᵢ and Δxᵢₙᵥₙ respectively represent a closed-loop small-signal state variable of a first distributed generation, a closed-loop small-signal state variable of a second distributed generation, a closed-loop small-signal state variable of an i^{th} distributed generation and a closed-loop small-signal state variable of an n^{th} A distributed generation, Δφ₁, Δφ₂, Δφᵢ and Δφₙ respectively represent a reactive power ancillary small-signal state variable of the first distributed generation, a reactive power ancillary small-signal state variable of the second distributed generation, a reactive power ancillary small-signal state variable of the i^{th} distributed generation and a reactive power ancillary small-signal state variable of the n^{th} distributed generation, the reactive power ancillary small-signal state variable Δφᵢ of the i^{th} distributed generation is determined by an expression:
$${\dot{ϕ}}_{i} = \frac{1 \text{/} {n}_{Qi}}{{\sum }_{i = 1}^{n} 1 \text{/} {n}_{Qi}} {\sum }_{i = 1}^{n} {Q}_{i} - {Q}_{i} ,$$
\dot{φ}ᵢ represents a change rate of the reactive power ancillary small-signal state variable of the i^{th} distributed generation, Qᵢ represents a reactive power actually outputted by the i^{th} distributed generation, n_{Qi} represents a voltage droop characteristic coefficient of the i^{th} distributed generation, n represents a number of the distributed generations, Δγ represents a voltage ancillary small-signal state variable of the distributed generation, the voltage ancillary small-signal state variable Δγ of the distributed generation is determined by an expression:
$$\dot{γ} = {V}_{i}^{*} - \frac{1}{n} {\sum }_{i = 1}^{n} {V}_{odi} ,$$
\dot{γ} represents a change rate of the voltage ancillary small-signal state variable of the distributed generation, V*ᵢ represents an expected value of an average voltage of the i^{th} distributed generation, V_{odi} represents a d-axis component of an output voltage of the i^{th} distributed generation in a reference coordinate system dq, Aᵢₙᵥ represents a state matrix of the distributed generation, ΔV_{bDQ} represents the small-signal state variable of a bus voltage in a common reference coordinate system DQ, ΔV_{bDQ}=[ΔV_{bDQ1}, ΔV_{bDQ2}, . . . , ΔV_{bDQi}, . . . , ΔV_{bDQm}]^{T}, ΔV_{bDQ1}, ΔV_{bDQ2}, ΔV_{bDQ1} and ΔV_{bDQm} respectively represent a small-signal state variable of a voltage of a first bus, a small-signal state variable of a voltage of a second bus, a small-signal state variable of a voltage of an l^{th} bus and a small-signal state of a voltage of an m^{th} bus in the common reference coordinate system DQ, m represents a number of the buses, Bᵢₙᵥ represents an input matrix of the distributed generation to the bus voltage, Δu represents a secondary voltage small-signal control amount of the distributed generation, Δu=[Δu₁, Δu₂, . . . , Δuᵢ, . . . , Δuₙ]^{T}, Δu₁, Δu₂, Δuᵢ and Δuₙ respectively represent the secondary voltage small-signal control amount of the first distributed generation, the secondary voltage small-signal control amount of the second distributed generation, the secondary voltage small-signal control amount of the i^{th} distributed generation and the secondary voltage small-signal control amount of the n^{th} distributed generation, Bᵤ represents an input matrix of the distributed generation to the secondary voltage small-signal control amount, Δuᵢ=K_{Qi}Δy_{invQi}(t−τᵢ)+K_{Vi}Δy_{invV}(t−τᵢ), t represents a current time, τᵢ represents a communication delay between a local controller of the i^{th} distributed generation and a centralized secondary voltage controller of a microgrid, K_{Qi} and K_{Vi} respectively represent a reactive power control coefficient of the i^{th} distributed generation and a voltage control coefficient of the i^{th} distributed generation, Δy_{invQi} represents a reactive power output small-signal state variable of the i^{th} distributed generation, Δy_{invQ} and Δy_{invV} respectively represent a reactive power output small-signal state variable of the distributed generation and a voltage output small-signal state variable of the distributed generation, and C_{invQ} and C_{invV} respectively represent a reactive power output matrix of the distributed generation and a voltage output matrix of the distributed generation.

3. The microgrid delay margin calculation method based on the critical characteristic root tracking according to claim 2, wherein, the distributed generation closed-loop small-signal model of the voltage feedback control amount comprising the communication delay established according to the static feedback output is:
$$\{ \begin{matrix}Δ {\dot{x}}_{inv} = {A}_{inv} Δ {x}_{inv} + {\sum }_{i = 1}^{n} {\overline{A}}_{di} Δ {x}_{inv} ( t - {τ}_{i} ) + {B}_{inv} Δ {V}_{bDQ} \\ Δ {i}_{oDQ} = {C}_{invc} Δ {x}_{inv} \end{matrix} ,$$
Ā_{di} represents a delay state matrix of the i^{th} distributed generation, Ā_{di}=[0 . . . BᵤᵢK_{Qi}C_{invQi}+BᵤᵢK_{Vi}C_{invV} . . . 0], Bᵤᵢ represents an input matrix of the i^{th} distributed generation to the secondary voltage small-signal control amount, C_{invQi} represents a reactive power output matrix of the i^{th} distributed generation, Δi_{oDQ} represents a small-signal state variable of an output current of the distributed generation in the common reference coordinate system DQ, and C_{invQ} represents a current output matrix of the distributed generation.

4. The microgrid delay margin calculation method based on the critical characteristic root tracking according to claim 3, wherein, the microgrid small-signal model is
$$\dot{x} = Ax + {\sum }_{i = 1}^{n} {A}_{di} x ( t - {τ}_{i} ) ,$$
x and \dot{x} respectively represent a microgrid small-signal state variable and a change rate of the microgrid small-signal state variable, x=[Δxᵢₙᵥ Δi_{lineDQ} Δ_{loadDQ}]^{T}, Δi_{lineDQ} represents a small-signal state variable of a current of a connection line between the plurality of buses connected with the distributed generations in the common reference coordinate system DQ, the small-signal state variable of the current of the connection line between the bus connected with the i^{th} distributed generation and the bus connected with a jth distributed generation in the common reference coordinate system DQ is:
$$\{ \begin{matrix}Δ {\dot{i}}_{lineDij} = - \frac{{r}_{lineij}}{{L}_{lineij}} Δ {i}_{lineDij} + {ω}_{0} Δ {i}_{lineQij} + \frac{1}{{L}_{lineij}} ( Δ {V}_{busDi} - Δ {V}_{busDj} ) \\ Δ {\dot{i}}_{lineQij} = - \frac{{r}_{lineij}}{{L}_{lineij}} Δ {i}_{lineQij} - {ω}_{0} Δ {i}_{lineDij} + \frac{1}{{L}_{lineij}} ( Δ {V}_{busQi} - Δ {V}_{busQj} )\end{matrix} ,$$
Δi_{lineDij} and Δi_{lineDij} respectively represent a D-axis small-signal component and a change rate of a current of a connection line ij in the common reference coordinate system DQ, Δi_{lineQij} and Δi_{lineQij} respectively represent a Q-axis small-signal component and the change rate of the current of the connection line ij in the common reference coordinate system DQ, rₗᵢₙₑᵢⱼ and Lₗᵢₙₑᵢⱼ respectively represent a line resistance and a line inductance of the connection line ij, ω₀ represents a rated angular frequency of a microgrid, ΔV_{busDi} and ΔV_{busQi} respectively represent a D-axis component and a Q-axis component of the voltage of the bus connected with the i^{th} distributed generation in the common reference coordinate system DQ, ΔV_{busDj} and V_{busQj} respectively represent the D-axis component and the Q-axis component of the voltage of the bus connected with the j^{th} distributed generation in the common reference coordinate system DQ, Δi_{loadDQ} represents a small-signal state variable of the current of a load connected with the bus in the common reference coordinate system DQ, the small-signal state variable of a current of the load connected with the l^{th} bus in the common reference coordinate system DQ is:
$$\{ \begin{matrix}Δ {\dot{i}}_{loadDt} = - \frac{{R}_{loadl}}{{L}_{loadl}} Δ {i}_{loadDl} + {ω}_{0} Δ {i}_{loadQl} + \frac{1}{{L}_{loadl}} Δ {V}_{busDl} \\ Δ {\dot{i}}_{loadQt} = - \frac{{R}_{loadl}}{{L}_{loadl}} Δ {i}_{loadQl} - {ω}_{0} Δ {i}_{loadDl} + \frac{1}{{L}_{loadl}} Δ {V}_{busQl}\end{matrix} ,$$
Δi_{loadDl} and Δi_{loadDl} and respectively represent the D-axis component and a change rate of the current of the load connected with the l^{th} bus in the common reference coordinate system DQ, Δi_{loadQl} and Δi_{loadQl} respectively represent the Q-axis component and the its change rate of the current of the load connected with the filth bus in the common reference coordinate system DQ, R_{loadl} and L_{loadl} respectively represent a load resistance and a load inductance of the load connected with the l^{th} bus, ΔV_{busDl} and ΔV_{busQl} respectively represent the D-axis component and the Q-axis component of the voltage of the l^{th} bus in the common reference coordinate system DQ, and A_{di} and τᵢ respectively represent the delay state matrix of the i^{th} distributed generation and a delay of the i^{th} distributed generation.

5. The microgrid delay margin calculation method based on the critical characteristic root tracking according to claim 4, wherein, a method for obtaining the characteristic equation with the transcendental term from the microgrid small-signal model comprises as: when a plurality of the delays of the distributed generations are consistent, obtaining a characteristic equation of the microgrid small-signal model:
CE_{τ}(s, τ)=det(sI−A−A_{d}e−^{τs}), s represents a time domain complex plane parameter, τ represents a consistent delay time of each distributed generation of the distributed generations, CE_{τ}(⋅) represents the characteristic equation of the microgrid small-signal model obtained according to the consistent delay time τ of the each distributed generation, det(⋅) represents a matrix determinant, I represents a unit matrix, A_{d} represents a delay state matrix of the distributed generation,
$${A}_{d} = {\sum }_{i = 1}^{n} {A}_{di} ,$$
and e^{-τs} represents the transcendental term.

6. The microgrid delay margin calculation method based on the critical characteristic root tracking according to claim 5, wherein, performing the critical characteristic root tracking on the transcendent term to determine the delay margin meeting the requirement of the system stability includes: with a delay time ancillary variable as a variable of the characteristic equation, solving all pure virtual characteristic roots of the characteristic equation within a change cycle of the delay time ancillary variable, and selecting a minimum value as the delay margin meeting the requirement of the system stability from a plurality of critical delay times corresponding to the all pure virtual characteristic roots; wherein the delay time ancillary variable is a product of a distributed generation delay and a virtual characteristic root amplitude.
